(19) United States
(12) Patent Application Publication
(10) Pub. No.: US 2018/0331016 A1
(43) Pub. Date: Nov. 15, 2018

(54) THREE-DIMENSIONAL HEAT-ABSORBING DEVICE

(71) Applicant: INDUSTRY FOUNDATION OF CHONNAM NATIONAL UNIVERSITY, Gwangju (KR)

(72) Inventor: Ki Ju KANG, Damyang-gun, Jeollanam-do (KR)

(73) Assignee: INDUSTRY FOUNDATION OF CHONNAM NATIONAL UNIVERSITY, Gwangju (KR)

(21) Appl. No.: 15/774,055

(22) PCT Filed: Nov. 12, 2015
(86) PCT No.: PCT/KR2015/012160

§ 371 Date: May 7, 2018

(30) Foreign Application Priority Data
Nov. 11, 2015 (KR) 10-2015-0158278

(51) Int. Cl. H01L 23/427; H05K 7/20; H01L 23/34; C09K 5/04; F28D 15/02

(52) U.S. Cl. CPC H01L 23/427; H05K 7/20; F28D 15/02; C09K 5/047; H01L 23/345

(57) ABSTRACT

A three-dimensional heat absorbing device including: an airtight member defining an outer appearance of the three-dimensional heat absorbing device; a first space connected to each other inside the airtight member in a three-dimensional lattice structure; and a second space constituting a space not occupied by the first space among an internal space of the airtight member. In the device, at least one of the first space and the second space forms a channel for working fluid steam, and a wick to which liquefied working fluid is absorbed are provided along inner surfaces of the channel.

### TECHNICAL FIELD

The present disclosure relates to a heat absorbing device that absorbs heat transferred from an external heat source to suppress an increase in the temperature of the heat source.

### BACKGROUND ART

In general, in various kinds of products including an electronic component such as a semiconductor, heat generated during an operation needs to be effectively discharged to the outside to avoid performance deterioration. In the related art, a heat pipe has been widely known as a very effective means for transferring heat generated by a heat source to another place. An operating principle and a development status of such a heat pipe are disclosed in Amir Faghri's paper (Amir Faghri, Review and Advances in Heat Pipe Science and Technology, ASME Journal of Heat Transfer, Vol. 134, pp. 123001-1 to 18, 2012.).

FIG. 1 shows a structure of the conventional heat pipe, FIG. 1A is a longitudinal sectional view of the heat pipe, and FIG. 1B is a cross-sectional view of the heat pipe. A linear heat pipe 1 of FIG. 1 includes a long cylindrical airtight container 11 and a porous wick 14 formed on an inner wall of the airtight container 11. The wick 14 is immersed in a liquefied working fluid, and a channel 12 through which a gaseous working fluid phase-changed by heat passes is formed inside the wick 14. An internal space of the airtight container 11 is partitioned into an evaporation portion A, an insulation portion B, and a condensation portion C from the left side of the drawing in a longitudinal direction. The working fluid is evaporated in the wick 14 in the evaporation portion A by heat transferred from an external heat source (not shown) to absorb heat. Accordingly, the pressure of the channel 12 increases so that the gaseous working fluid moves to the condensation portion C. The gaseous working fluid reaching an opposite condensation portion C is condensed into the liquid working fluid to emit heat, is absorbed to the wick 14 in the condensation portion C, and then flows back to the evaporation portion A along the wick 14 by a capillary effect. The heat generated by the external heat source may be effectively absorbed and transferred through a cycle process including the evaporation, the condensation, and the movement of the working fluid.

Meanwhile, a flat heat pipe using a heat transfer principle of such a linear heat pipe has been also known. For example, FIG. 2A shows an example of a flat heat pipe serving as a wick since a gap between the upper and lower surfaces of an intermediate member 24 is smaller than that of a lower member 21 (Novel Concepts, Inc. http://www.novelconceptsinc.com/). FIG. 2B shows an example of a flat heat pipe in which a channel of a working fluid is opened (Celsia Inc. http://celsiainc.com/vapor-chamber-one-piece-design/). The flat heat pipe of FIGS. 2A and 2B is an example designed for cooling a product in which a small amount of heat is transferred, such as an electronic component, and the thickness of the flat heat pipe is as thin as 1 mm. FIG. 2C shows an example of a flat heat pipe used when a large amount of heat transfer is required as in a blast deflector of a jet plane, a channel of a working fluid being opened, which is like FIG. 2B (D. T. Queheillalt, G Carbajal, G P. Peterson, H. N. G Wadley, International Journal of Heat and Mass Transfer vol. 51, pp. 312-326, 2008.). Such a flat heat pipe is also referred to as a heat spreader in a sense that heat applied below a plate is transferred to the whole area.

The conventional linear or flat heat pipe shown in FIGS. 1 and 2 has various advantages in that the heat pipe has a simple structure, is operated even when a temperature gradient is not large, and has a fast response speed, and a heating unit and a cooling unit may be separated from each other or roles of the heating unit and the cooling unit may be switched mutually. Thus, the linear or flat heat pipe has been widely used in various fields.

However, in the case of the conventional linear or flat heat pipe, since a transferred calorie is relatively low and thermal storage performance in addition to a function of simply transferring heat is not considered, a separate forcible cooling means such as a fan is necessarily required to maintain an original function when an excessive calorie is absorbed. The separate forcible cooling means requires additional energy consumption and causes noise, and the outer volume of the heat pipe is excessively increased to achieve sufficient natural cooling without the forcible cooling means. Further, since a heat transfer direction of the linear or flat heat pipe is limited, design of a product including the heat pipe is delimited. Thus, in spite of the advantages of the conventional linear or flat heat pipe, an application range of the heat pipe is limited.

Meanwhile, in recent years, a so-called phase change material (PCM) such as an ice pack, in which large latent heat is absorbed or emitted during a phase changing process between a solid phase and a liquid phase, is spotlighted as a heat storage means. However, since such a PCM generally has low thermal conductivity, it has been known that more effective heat storage performance may be achieved as compared to a case where a product is used while being filled in a porous metal structure having high thermal conductivity (K. J. Kang, Progress in Materials Science, Vol. 69, pp. 213-307, 2015.). A heat storage device based on such a PCM is also an excellent heat absorbing device. Even when heat is applied from the outside, a temperature does not increase as long as a phase change from a solid phase to a liquid phase continues. However, when the phase change is completed, heat storage performance resulting from the latent heat is lost, and thus there is a lack of a performance maintaining property as the heat absorbing device.

### DISCLOSURE

### Technical Problem

The present disclosure provides a heat absorbing device having a compact and firm structure, which has a high heat transfer rate and high heat capacity, and thus may be operated at a constant rate.

### Technical Solution

The present inventors have found that there is a need to provide heat storage performance together with an improvement in a heat transfer rate in a process of developing a heat absorbing device that may be operated at a constant rate without a general forcible cooling means and has a compact structure. Thus, the present inventors expand or diversify a heat transfer system of a device in three dimensions, grant heat storage performance to a part of the diversified heat transfer system as needed, and embody these contents, thereby leading to the present invention. Recognition of the above-mentioned problems and the subject matter of the present disclosure based thereon will be described below.

(1) A three-dimensional heat absorbing device may include an airtight member defining an outer appearance of the three-dimensional heat absorbing device, a first space connected inside the airtight member in a three-dimensional lattice structure, and a second space constituting a space not occupied by the first space among an internal space of the airtight member, in which at least one of the first space and the second space forms a channel for working fluid steam, and a wick to which liquefied working fluid is absorbed is provided along inner surfaces of the channel.

(2) At least one of the first space and the second space may be filled with the wick, and the phase-changed working fluid may be moved in a boundary between the first space and the second space.

(3) The boundary between the first space and the second space may be configured by a wall.

(4) The wick may be provided on an inner surface of the wall of the first space and the second space, and the first space and the second space may form a channel for the working fluid steam.

(5) The working fluid may be a homogeneous or heterogeneous material.

(6) A wick may be provided on an inner surface of a wall of any one of the first space and the second space to form the channel for the working fluid steam.

(7) An inside of a space not forming the channel for the working fluid steam among the first space and the second space may be filled with a phase change material.

(8) The three-dimensional heat absorbing device may further include a porous heat transfer member immersed in the phase change material.

(9) The porous heat transfer member may be any one of foamed metal, lattice metal, and woven metal.

(10) A solid heat dissipation member may be provided in a space not forming the channel for the working fluid steam among the first space and the second space.

(11) The heat dissipation member may be any one of porous metal, solid metal, and a cooling fin.

(12) The wick may be any one of a metal net, felt, fiber, and permeable porous solid.

(13) The working fluid may be any one of water, ammonia, ethanol, helium, argon, nitrogen, lead, silver, and lithium.

(14) The phase change material may be any one of paraffin, lauric acid, and salt hydrate.

(15) A boundary between the first space and the second space may be a flat surface or a curved surface.

### Effect

In a three-dimensional heat absorbing device according to the present disclosure, a heat transfer system inside the device is three-dimensionally extended and diversified, so that a heat transfer rate may be improved. In addition, heat storage performance is provided in a part of the heat transfer system, so that the heat absorbing device may be operated at a constant rate generally without a separate forcible cooling means and only by natural cooling in a state in which an increase in the temperature is suppressed. Further, such a heat transfer rate and/or heat storage performance is/are improved, so that a device in which energy consumption and noise generation are suppressed may be compactly designed. Further, in the three-dimensional heat absorption device according to the present disclosure, a heat transfer channel is connected in three-dimensions, so that durability against an external force is improved. Further, an operating direction is not limited, so that a system including the heat absorbing device may be freely designed.

### DESCRIPTION OF DRAWINGS

FIG. 1 shows a structure of a linear heat pipe according to the related art;

FIG. 2 shows an example of a flat heat pipe according to the related art; and

FIGS. 3 to 6 show structures of three-dimensional heat absorbing devices according to different embodiments of the present disclosure.

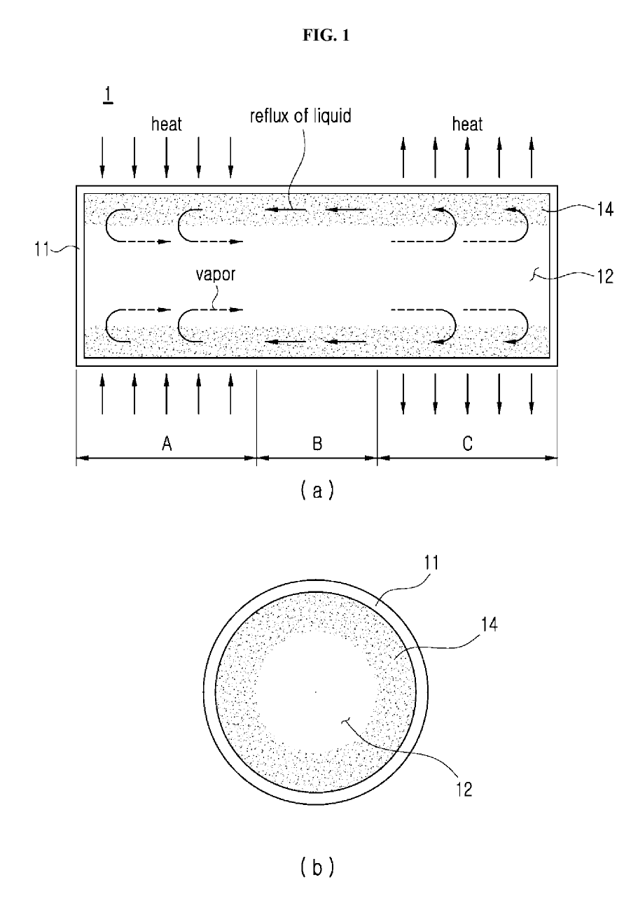

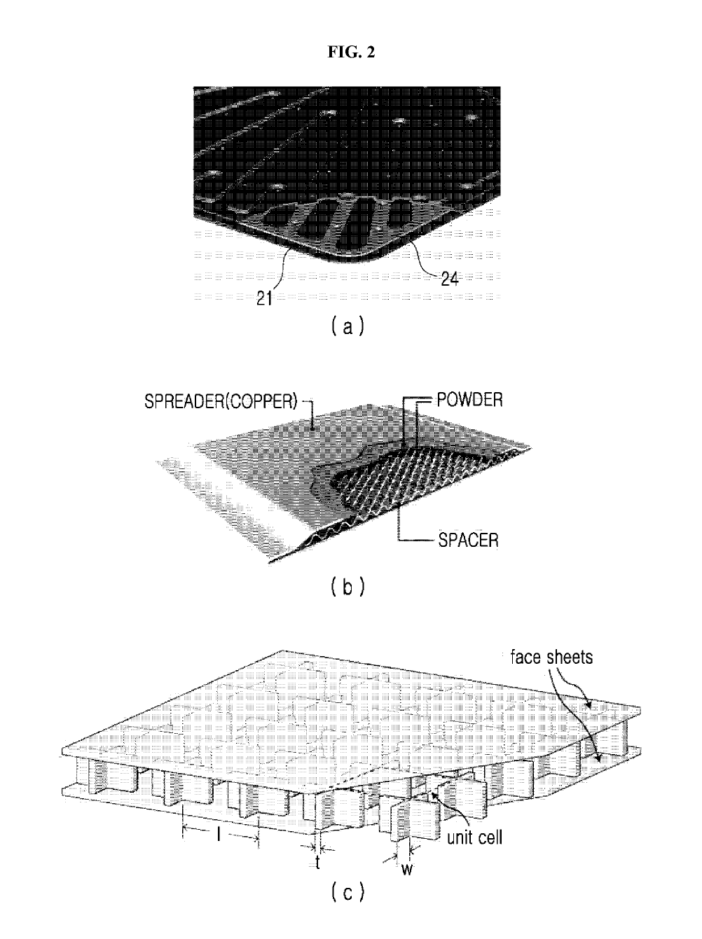

### BEST MODE

Hereinafter, the present disclosure will be described in detail through embodiments. Prior to this, terms and words used in the present specification and the appended claims should not be interpreted as being limited to general or bibliographical meanings, and should be interpreted as meanings and concepts matched with the technical spirit of the present disclosure based on a principle in which an inventor could properly define concepts of the terms to optimally describe his/her invention. Thus, configurations of embodiments described in the present specification merely correspond to the most preferable embodiment of the present disclosure, and do not represent all the technical spirit of the present disclosure. Thus, it should be understood that there may be various equivalents and modifications for which they may be substituted at a time of filling the present disclosure. Meanwhile, in the accompanying drawings, the same components or equivalents may be designated by the same reference numerals. Further, throughout the specification, when it is written that a specific part “includes” a specific component, this means that that specific part does not exclude other components but may further include other components unless otherwise described.

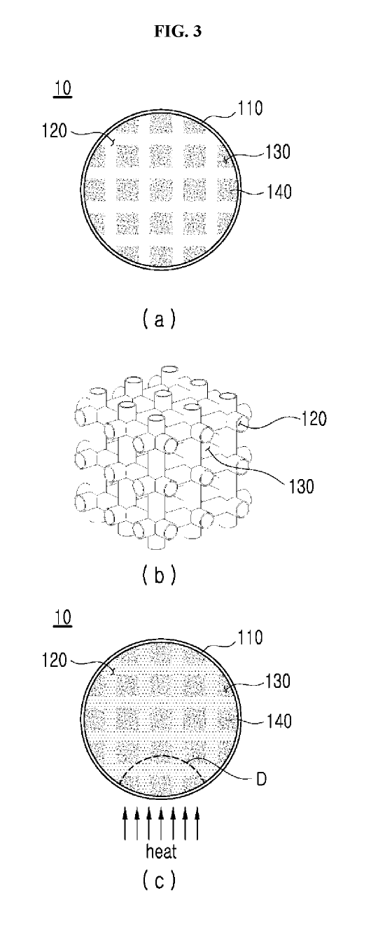

FIG. 3 shows a heat absorbing device 10 according to a first embodiment of the present disclosure.

FIG. 3A shows a two-dimensional structure of the heat absorbing device 10. As shown in FIG. 3A, the heat absorbing device 10 includes an airtight member 110 defining an outer appearance of the device, and an internal space of the airtight member 110 is partitioned into first space 120 and second space 130. That is, the second space 130 is configured by a space not occupied by the first space 120 among the internal space of the airtight member 110. In the present embodiment, the first space 120 forms a channel of working fluid steam, and an inside of the second space 130 is filled with a porous material for absorbing a liquefied working fluid, to constitute a wick 140. The outer shape of the airtight member 110 is not particularly limited, and may be properly determined according to a system to which the heat absorbing device 10 is applied. In the drawing, the outer shape of the airtight member 110 is arbitrarily shown as a blank space of the wick 140 such that a boundary between the outside and the inside of the device is defined.

In this case, the airtight member 110 is not particularly limited as long as the airtight member 110 is impermeable and has a predetermined thermal conductivity. The working fluid is not particularly limited as long as the working fluid is a material that may be evaporated and condensed according to an operating temperature and an operating pressure of the heat absorbing device 10. All liquids such as water, ammonia, and ethanol, and gases such as helium, argon, and nitrogen, as well as solids such as lead, silver, and lithium may be used under the room temperature and the atmospheric pressure. For example, even when the material is solid under the room temperature and the atmospheric pressure, if the material is in a liquid state or a gaseous state in the operating temperature and the operating pressure of the heat absorbing device 10, the material may be used as the working fluid. The wick 140 is formed of porous materials such as a metal net, felt, fiber, and permeable porous solid such that the liquefied working fluid may be moved by a capillary effect. The internal pressure of the airtight member 110 may be maintained to be lower than the atmospheric pressure such that evaporation and liquefaction occurs at a predetermined temperature.

FIG. 3B is a stereoscopic view illustrating the first space 120. In this case, the first space 120 is connected to each other in a three-dimensional lattice structure, and reflectively, the second space 130 is connected to each other through a blank space of FIG. 3B. However, a matter shown in FIG. 3B represents, in three dimensions, the shape of the channel of the first space 120, which functions as a passage for a vapor-phase working fluid. Such a shape of the channel is defined by the wick 140 filled in the second space 130, which does not indicate that a boundary between the first space 120 and the second space 130 is configured by a separate wall. Thus, in the present embodiment, the phase-changed working fluid may move through the boundary between the first space 120 and the second space 130.

Although the three-dimensional lattice shape of the first space 120 has a hexagonal lattice shape as in the embodiment, and thus the channel has a straight line shape, the present disclosure is not limited thereto. For example, the boundary between the first space 120 and the second space 130 may be configured to have a flat shape or a curved shape, the shape of the channel as a passage for the working fluid may be configured to have a straight line shape or a curved line shape, and the cross sections of the channel may change according to positions.

FIG. 3C is an operational conceptual view of the heat absorbing device 100. It is scheduled that the first space 120 is filled with the gaseous working fluid and the liquefied working fluid is absorbed in the wick 140 of the second space 130. When heat is transferred from an external heat source (not shown) to an external partial area D of the heat absorbing device 10, the liquefied working fluid immersed in the wick 140 of the second space 130 absorbs the heat to be converted into the gaseous working fluid, and the gaseous working fluid is moved to become farther away from the heat source along the channel of the first space 120 by an increased vapor pressure. The gaseous working fluid away from the heat source emits heat to the outside, is converted into the liquefied working fluid, and is absorbed to the wick 140 again. The absorbed liquefied working fluid flows back to the wick 140 near the heat source along the channel of the second space 130 by a capillary effect. The heat generated by the external heat source may be effectively absorbed and transferred through a cycle process including the evaporation, the condensation, and the movement of the working fluid.

The heat absorbing device 10 according to the embodiment of FIG. 3 has the same basic heat transfer principle as that of the heat pipe according to the related art, but has the following advantages. First, since the volume of the wick 140 formed of a permeable porous material is much larger than the volume of the heat pipe according to the related art in a three-dimensionally extended heat transfer system, the amount of the working fluid also increases. As the amount of the working fluid having high specific heat increases, heat capacity of the entire heat absorbing device 10 increases, so that an increase in the temperature of the heat absorbing device 10 itself may be significantly delayed as compared to thermal energy absorbed by the external heat source, and heat may be absorbed by the external heat source at a constant rate even without a separate forcible cooling means. Second, the wick 140, which fills the second space 130 to partition the first space 120, is formed of a permeable porous material, and thus may serve to support the device 10 against an external force as well as absorb and store the liquefied working fluid. That is, the wick 140 occupies the internal space of the airtight member 110 except for the first space 120 constituting the channel for the working fluid steam, and thus may also serve as a lightweight structural material for supporting a load. Third, the linear or flat heat pipe according to the related art is a one-dimensional or two-dimensional heat pipe, but the heat absorbing device 10 according to the embodiment is a kind of a three-dimensional heat pipe. When heat is applied from the external heat source to a part of the airtight member 110, the phase-changed working fluid steam close to the heat source moves through a plurality of adjacent channels, and the condensed working fluid on an opposite side moves from the entire space formed of the permeable porous material toward the heat source by a capillary effect. Therefore, heat transfer is quickly performed, and the heat absorbing device 10 may be operated using the same heat transfer mechanism regardless of the position and the direction of the heat source applied to the airtight member 110.

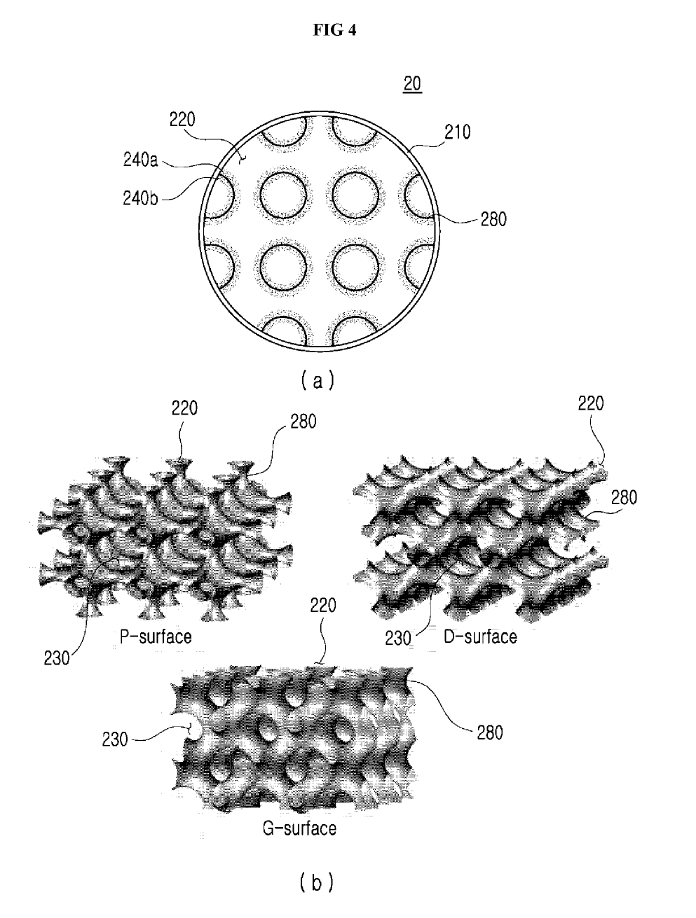

FIG. 4 shows a structure of a heat absorbing device 20 according to a second embodiment of the present disclosure.

FIG. 4A shows a two-dimensional structure of the heat absorbing device 20. As shown in FIG. 4A, the heat absorbing device 20 includes an airtight member 210, which is like the first embodiment, and an internal space of the airtight member 210 is partitioned into first space 220 and second space 230. Further, in the present embodiment, an outer shape and a material of the airtight member 210, the kind of the working fluid, and a material of wicks 240a and 240b may be the same as those according to the first embodiment.

In the present embodiment, unlike the first embodiment, a boundary between the first space 220 and the second space 230 is configured by a wall 280, and the wicks 240a and 240b are provided on an inner surface of the wall 280, so that the first space 220 and the second space 230 independently form a channel for the working fluid steam. In this case, unlike the first embodiment, since the boundary between the first space 220 and the second space 230 is formed by the wall 280, it is impossible to move the phase-changed working fluid. The working fluid operated in the first space 220 and the second space 230 may be a homogeneous or heterogeneous material.

FIG. 4B is a stereoscopic view illustrating the first space 220. In this case, the first space 220 is connected in a three-dimensional lattice structure, and reflectively, the second space 230 is connected to each other through a structural blank space of FIG. 4B. The three-dimensional lattice structure forming the first space 220 is a hollow thin-film structure, and such a thin film configures the wall 280 of the first space 220 and the second space 230. In the embodiment, the surface of the hollow thin-film structure may be configured by, for example, a Triply Periodic Minimal Surface (TPMS) (S. Hyde et al., The Language of Shape, Elsevier, Danvers, Mass., USA 1996), and three kinds of TPMSs such as a P-surface, a D-surface, and a G-surface are shown in FIG. 4B. The TPMS is configured by continuous and smooth curved surfaces that do not intersect each other and have an average curvature of 0 regardless of positions, and the first space 220 and the second space 230 partitioned by the TPMS have similar shapes.

However, in the present embodiment, although the three-dimensional lattice shape of the first space 220 has a lattice shape having the TPMS, and thus the channel has a curved shape, the present disclosure is not limited thereto. For example, even in the present embodiment, the channel for the working fluid steam by the first space 220 may be configured by a straight line shown in FIG. 3B according to the first embodiment. In this case, the shape of the three-dimensional thin-film structure forming the first space 220 is the same as that of the channel of FIG. 3B. Further, the boundary between the first space 220 and the second space 230 may be configured to have a flat shape or a curved shape, the shape of the channel as a passage for the working fluid may be configured to have a straight line shape or a curved line shape, and the cross section of the channel may change according to positions.

Meanwhile, such a hollow thin-film structure may be manufactured through a process of manufacturing a template, forming a thin film, and removing the template inside the thin film, which is recently announced and related to manufacturing of the hollow thin-film structure. The template may be manufactured in a method of curing a thermosetting resin by using a photolithography technique or a method of weaving a porous truss structure by a wire. A material of the thin-film is not particularly limited as long as the material is permeable and has predetermined thermal conductivity, which is like the airtight member 210. For example, metal may be advantageously applied thereto.

Heat transfer of the heat absorbing device 20 according to the embodiment of FIG. 4 is performed through independent channels of the first space 220 and the second space 230. That is, when heat is transferred from the external heat source to a part of the outside of the heat absorbing device 20, the liquefied working fluid immersed in the wicks 240a and 240b of the first space 220 and the second space 230 absorbs the heat and thus is converted into the gaseous working fluid. The gaseous working fluid is moved to become farther away from the heat source along the first space 220 and the second space 230 by an increased vapor pressure. The gaseous working fluid away from the heat source emits heat to the outside, is converted into the liquefied working fluid, and is absorbed to the wicks 240a and 240b again. The absorbed liquefied working fluid is moved to the wicks 240a and 240b near the heat source along the channels of the first space 220 and the second space 230 by a capillary effect. The heat generated by the external heat source may be effectively absorbed and transferred through a cycle process including the evaporation, the condensation, and the movement of the working fluid. In this case, as described above, the working fluid in the first space 220 and the second space 230 may be a homogeneous or heterogeneous material.

The heat absorbing device 20 according to the embodiment of FIG. 4 uses the same basic heat transfer principle as that of the heat pipe according to the related art, but has the following advantages. First, the three-dimensional first space 220 and the three-dimensional second space 230 act as an independent channel for the working fluid, so that the rate and the amount of the heat transfer may increase. Further, when the working fluid in the first space 220 and the second space 230 is different, a plurality of heat transfer mechanisms having different heat transfer temperature ranges may be simultaneously implemented in one heat absorbing device 20. Second, since the volume of the wicks 240a and 240b formed of a permeable porous material is much larger than the volume of the heat pipe according to the related art in a three-dimensionally extended heat transfer system, which is like the first embodiment, the amount of the working fluid also increases. As the amount of the working fluid having high specific heat increases, heat capacity of the entire heat absorbing device 20 increases, so that an increase in the temperature of the heat absorbing device 20 itself may be significantly delayed as compared to thermal energy absorbed by the external heat source, and heat may be absorbed by the external heat source at a constant rate even without a separate forcible cooling means. Third, the thin-film wall 280 itself as a boundary through which the first space 220 and the second space 230 are partitioned configures an ideal lightweight structure that may support an external load. For example, a hollow truss structure having a kagome, octet, or pyramid lattice structure has excellent strength as compared to weight (H. N. G Wadley, Phil. Trans. R. Soc. A Vol. 364, pp. 31-68, 2006.). Further, it has been reported that the thin-film structure having the TPMS shape shown in FIG. 4B also has strength that is equal to that of the hollow truss structure (S. C. Han, J. W. Lee, K. Kang, Advanced Materials, Vol. 27, pp. 5506-5511, 2015). Thus, as the first space 220 and the second space 230 are partitioned by the thin-film wall 280, the heat absorbing device 20 may be supported against an external force. Fourth, like the first embodiment, the heat absorbing device 20 is operated as the three-dimensional heat pipe, and thus may be operated using the same heat transfer mechanism regardless of a position and a direction of the heat applied to the airtight member 110.

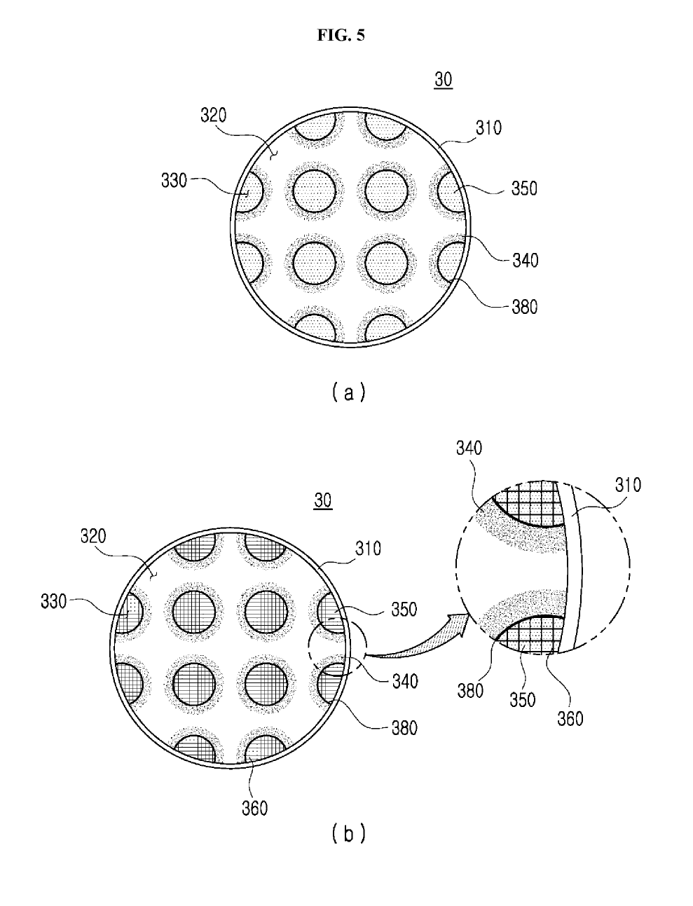

FIG. 5 shows a structure of a heat absorbing device 30 according to a third embodiment of the present disclosure.

FIG. 5A shows a two-dimensional structure of the heat absorbing device 30. As shown in FIG. 5A, the heat absorbing device 30 includes an airtight member 310, which is like the first embodiment, and an internal space of the airtight member 310 is partitioned into first space 320 and second space 330. Further, like the first embodiment, an outer shape and a material of the airtight member 310, the kind of the working fluid, and a material of a wick 340 may be equally applied. Further, like the second embodiment, since a boundary between the first space 320 and the second space 330 is formed by the thin-film wall 380, it is impossible to move the phase-changed working fluid. Further, a three-dimensional hollow thin-film structure forming the first space 320, a manufacturing method therefor, and a material of a thin film may be the same as those according to the second embodiment. Although it is shown in FIG. 5A that the first space 320 has a lattice shape having the TPMS, and thus the channel has a curved shape, the present disclosure is not limited thereto.

In the present embodiment, unlike the second embodiment, as the wick 340 is provided only on an inner surface of the wall 380 of the first space 320, only the first space 320 forms a channel for the working fluid steam, and the second space 330 is filled with, for example, a PCM 350 such as paraffin, lauric acid, and salt hydrate which have large latent heat of melting. In this case, immediate heat transfer from an external heat source is performed through the channel configured by the first space 320, and such immediate heat transfer is the same as the heat transfer by the working fluid in the first embodiment. The PCM 350 filled in the second space 330 serves as a heat storage means that gradually absorbs heat from the outside while being phase-changed from a solid phase to a liquid phase.

FIG. 5B shows a modification of the third embodiment. In FIG. 5B, the second space 330 further includes a porous heat transfer member 360 having high thermal conductivity and formed of metal. The porous heat transfer member 360 may be formed of permeable porous metal such as foamed metal, lattice metal, and woven metal (K. J. Kang, “Wire-woven cellular metals: the present and future”, Progress in Materials Science, Vol. 69, pp. 213-307, 2015), and are immersed in the PCM 360. Such porous heat transfer member 360 promotes a heat transfer rate to the PCM 360 having low thermal conductivity, thereby improving heat storage performance of the heat absorbing device 30.

The heat absorbing device 30 according to the embodiment of FIG. 5 has the following advantages as compared to a heat storage means based on a heat pipe or a PCM according to the related art. First, heat transfer to the PCM 350 of the second space 330 is immediately performed through the wall 380 having a wide surface area through the three-dimensional channel of the first space 320, so that responsiveness to heat absorption of the PCM may be improved. Second, when the melting temperature of the PCM 350 in the second space 330 is within an operating temperature range for immediate heat transfer in the first space 320, since the PCM 350 in the second space 330 surrounding the first space 320 has high latent heat of melting, even when unexpected high thermal energy is applied from the outside, the working fluid in the first space 320 is completely dried out, so that a possibility that a heat transfer function is lost is significantly lowered. Meanwhile, when the melting temperature of the PCM 350 in the second space 330 is outside an operating temperature range for heat transfer in the first space 320, the first space 320 and the second space 330 may be independently operated. Third, since the PCM 350 itself of the second space 330 has a high specific heat, even when heat transfer is performed in the first space 320 according to a heat pipe principle, the temperature of the entire heat absorbing device 30 increases slowly, and heat absorption may be performed at a constant rate even without a separate forcible cooling means. Fourth, like the second embodiment, the thin-film wall 380 itself as the boundary through which the first space 320 and the second space 330 are partitioned configures ideal lightweight structures that may support an external load, and thus may serve to support the heat absorbing device 30 from an external force. Fifth, like the first embodiment, the heat absorbing device 30 is operated as the three-dimensional heat pipe, and thus may be operated using the same heat transfer mechanism regardless of a position and a direction of the heat applied to the airtight member 310. Sixth, like the first embodiment, since a three-dimensional extended heat transfer system is provided, a heat transfer rate may increase, and thermal capacity of the device may increase.

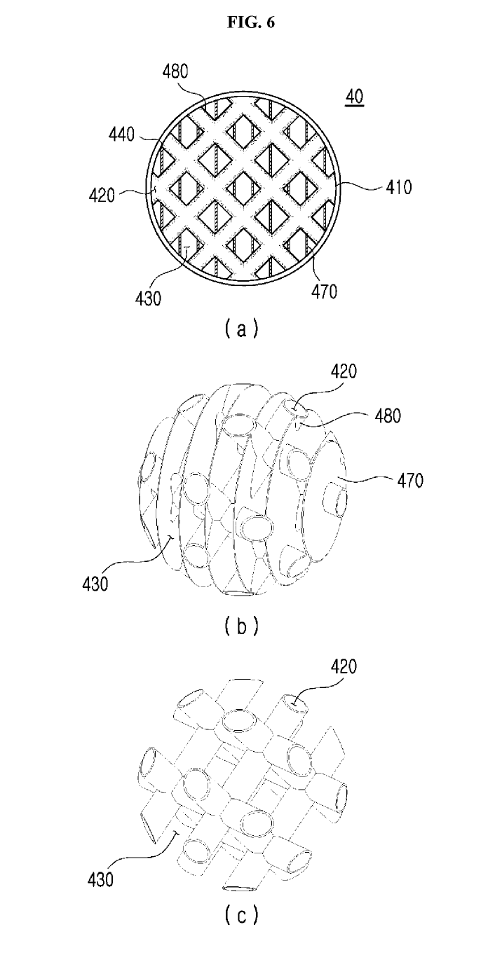

FIG. 6 shows a structure of a heat absorbing device 40 according to a fourth embodiment of the present disclosure.

FIGS. 6A and 6B show a two-dimensional structure and a three-dimensional structure of the heat absorbing device 40. As shown in FIG. 6A, the heat absorbing device 40 includes an airtight member 410, which is like the first embodiment, and an internal space of the airtight member 410 is partitioned into first space 420 and second space 430. Further, like the first embodiment, an outer shape and a material of the airtight member 410, the kind of the working fluid, and a material of a wick 440 may be equally applied. Further, like the second embodiment, since a boundary between the first space 420 and the second space 430 is formed by thin-film wall 480, it is impossible to move the phase-changed working fluid. Further, a three-dimensional hollow thin-film structure forming the first space 420, a manufacturing method therefor, and a material of a thin film may be the same as those according to the second embodiment. Although it is shown in FIG. 6A that the shape of a channel of the first space 420 has a hexagonal lattice shape and a linear shape, which is similar to FIG. 3B, the present disclosure is not limited thereto.

In the present embodiment, like the third embodiment, as a wick 440 is provided only on an inner surface of the wall 480 of the first space 420, only the first space 420 forms a channel for working fluid steam. However, unlike the third embodiment, the second space 430 may have heat dissipation members 470 such as cooling fins as shown in FIGS. 6A and 6B or may be completely emptied as shown in FIG. 6C. The heat dissipation members 470 may be formed of porous metal or solid metal in addition to the cooling fins, and thus may fill the entirety or a part of the second space 430. In this case, immediate heat transfer is performed in the first space 420 using the same principle as that of the heat pipe, and heat transfer by conduction, radiation, and convection is performed in the second space 430 using the heat dissipation members 470 or an empty space. The heat transfer mechanism in the second space 430 may be advantageously applied when the volume of the second space 430 is relatively larger than that of the first space 420.

The heat absorbing device 40 according to the embodiment of FIG. 6 has the following advantages as compared to the heat pipe according to the related art. First, when the volume of the second space 430 is relatively larger than that of the first space 420, heat transfer by conduction, radiation, and convection is induced using the second space 430 itself or the heat dissipation members 470, so that heat absorption may be performed at a constant rate even without a separate forcible cooling means. Second, in particular, when the heat dissipation members 470 filled in the second space 430 are completely filled with non-porous (solid) materials such as metal, the first space 420 may be formed simply by drilling a non-porous material bulk, so that the heat absorbing device 40 may be easily manufactured, structural strength may be improved, the heat absorbing device 40 has high thermal capacity of the non-porous materials, and thus heat absorption may be performed at a constant rate even without a separate forcible cooling means. Third, even when the second space 430 is emptied or the heat dissipation members 470 are not completely filled, like the second embodiment, the thin-film wall 480 itself as the boundary through which the first space 420 and the second space 430 are partitioned configure ideal lightweight structures that may support an external load, and thus may serve to support the heat absorbing device 40 from an external force. Fourth, like the first embodiment, the heat absorbing device 20 is operated as the three-dimensional heat pipe, and thus may be operated using the same heat transfer mechanism regardless of a position and a direction of the heat applied to the airtight member 410. Fifth, like the first embodiment, since a three-dimensional extended heat transfer system is provided, a heat transfer rate may increase, and thermal capacity of the device may increase.

As described above, in a three-dimensional heat absorbing device according to the present disclosure, a heat transfer system inside the device is three-dimensionally extended and diversified, so that a heat transfer rate may be improved. In addition, heat storage performance is provided in a part of the heat transfer system, so that the heat absorbing device may be operated at a constant rate generally without a separate forcible cooling means and only by natural cooling in a state in which an increase in the temperature is suppressed. Further, such a heat transfer rate and/or heat storage performance is/are improved, so that a device in which energy consumption and noise generation are suppressed may be compactly designed. Further, in the three-dimensional heat absorption device according to the present disclosure, since a heat transfer channel is connected in three-dimensions, an operating direction is not limited, so that a system including the heat absorbing device may be freely designed.

The above description relates to detailed embodiments of the present disclosure. The above-described embodiments of the present disclosure are not understood as limiting a matter disclosed for description or the scope of the present disclosure. Further, it should be understood that those skilled in the art may deduce various changes and modifications without departing from the essence of the present disclosure. For example, in the above-described embodiments, the roles performed by the first space and the second space may be changed mutually. Further, although being described in the embodiments, the working fluid and the phase change material filled in the heat absorbing device may be properly selected and used according to an operating temperature and an operating pressure range. Thus, it should be understood that all the modifications and the changes correspond to the scope of the present disclosure disclosed in the appended claims or equivalents thereto.

1. A three-dimensional heat absorbing device comprising:
an airtight member defining an outer appearance of the three-dimensional heat absorbing device;
a first space connected to each other inside the airtight member in a three-dimensional lattice structure; and
a second space constituting a space not occupied by the first space among an internal space of the airtight member,
wherein at least one of the first space and the second space forms a channel for working fluid steam, and a wick to which liquefied working fluid is absorbed are provided along inner surfaces of the channel.

2. The three-dimensional heat absorbing device of claim 1, wherein at least one of the first space and the second space is filled with the wick, and the phase-changed working fluid is moved in a boundary between the first space and the second space.

3. The three-dimensional heat absorbing device of claim 1, wherein a boundary between the first space and the second space is configured by a wall.

4. The three-dimensional heat absorbing device of claim 3, wherein the wick is provided on an inner surface of the wall of the first space and the second space, and the first space and the second space forms a channel for the working fluid steam.

5. The three-dimensional heat absorbing device of claim 4, wherein the working fluid is a homogeneous or heterogeneous material.

6. The three-dimensional heat absorbing device of claim 3, wherein a wick is provided on an inner surface of a wall of any one of the first space and the second space to form the channel for the working fluid steam.

7. The three-dimensional heat absorbing device of claim 6, wherein an inside of a space not forming the channel for the working fluid steam among the first space and the second space is filled with a phase change material.

8. The three-dimensional heat absorbing device of claim 7, further comprising:
a porous heat transfer member immersed in the phase change material.

9. The three-dimensional heat absorbing device of claim 8, wherein the porous heat transfer member is any one of foamed metal, lattice metal, and woven metal.

10. The three-dimensional heat absorbing device of claim 6, wherein a solid heat dissipation member is provided in a space not forming the channel for the working fluid steam among the first space and the second space.

11. The three-dimensional heat absorbing device of claim 10, wherein the heat dissipation member is any one of porous metal, solid metal, and a cooling fin.

12. The three-dimensional heat absorbing device of claim 1, wherein the wick is any one of a metal net, felt, fiber, and permeable porous solid.

13. The three-dimensional heat absorbing device of claim 1, wherein the working fluid is any one of water, ammonia, ethanol, helium, argon, nitrogen, lead, silver, and lithium.

14. The three-dimensional heat absorbing device of claim 8, wherein the phase change material is any one of paraffin, lauric acid, and salt hydrate.

15. The three-dimensional heat absorbing device of claim 1, wherein the boundary between the first space and the second space is a flat surface or a curved surface.
